(19) United States
(12) Patent Application Publication
(10) Pub. No.: US 2024/0145516 A1
(43) Pub. Date: May 2, 2024

(54) IMAGING DEVICE, METHOD FOR DRIVING THE SAME, AND ELECTRONIC DEVICE

(71) Applicant: SONY SEMICONDUCTOR SOLUTIONS CORPORATION, KANAGAWA (JP)

(72) Inventor: MASAHIKO NAKAMIZO, KANAGAWA (JP)

(21) Appl. No.: 18/548,213

(22) PCT Filed: Feb. 24, 2022
(86) PCT No.: PCT/JP2022/007608

§ 371 Date: Aug. 28, 2023

(30) Foreign Application Priority Data
Mar. 5, 2021 (JP) 2021-035742

(51) Int. Cl. H01L 27/146; H04N 25/778; H04N 25/78

(52) U.S. Cl. CPC H01L 27/14641; H01L 27/14612; H04N 25/778; H04N 25/78

(57) ABSTRACT

There is provided an imaging device capable of suppressing a decrease in quantum efficiency, and an electronic device using the imaging device. An imaging device of the present disclosure includes: a pixel array unit arranged in a matrix in units of a pixel group including a plurality of pixels that performs photoelectric conversion; a pixel transistor provided corresponding to each pixel group and including a plurality of transistors; and a circuit that controls a threshold voltage of at least one transistor of the plurality of transistors.

### TECHNICAL FIELD

Embodiments of the present disclosure relate to an imaging device, a method for driving the same, and an electronic device.

### BACKGROUND ART

An imaging device having a structure in which a light receiving layer provided with a photodiode and a layer provided with a pixel transistor are laminated is known (see Patent Document 1, for example). By adopting such a laminated structure, the dynamic range is increased by increasing the area of the photodiode and the transistor area per unit substrate area.

### CITATION LIST

### Patent Document

Patent Document 1: Japanese Patent Application Laid-Open No. 2020-88380

Patent Document 2: Japanese Patent Application Laid-Open No. 2018-74268

### SUMMARY OF THE INVENTION

### Problems to be Solved by the Invention

However, in the imaging device of Patent Document 1, since the pixel area increases, there is a problem that the pixel size cannot be reduced.

The present disclosure provides an imaging device capable of easily increasing the dynamic range without increasing the pixel size, a method for driving the same, and an electronic device.

### Solutions to Problem

An imaging device according to a first aspect of the present disclosure includes: a pixel array unit arranged in a matrix in units of a pixel group including a plurality of pixels that performs photoelectric conversion; a pixel transistor provided corresponding to the pixel group and including a plurality of transistors; and a circuit that controls a threshold voltage of at least one transistor of the plurality of transistors.

In the imaging device according to the first aspect, the pixel transistor may include a reset transistor, an amplification transistor, and a selection transistor.

In the imaging device according to the first aspect, the transistor whose threshold voltage is controlled may be at least one of the reset transistor or the selection transistor.

In the imaging device according to the first aspect, the transistor whose threshold voltage is controlled may be arranged in a well region, and the circuit may control a potential applied to the well region.

In the imaging device according to the first aspect, the plurality of transistors constituting the pixel transistor may be n-channel MOS transistors.

In the imaging device according to the first aspect, the plurality of transistors constituting the pixel transistor may be p-channel MOS transistors.

In the imaging device according to the first aspect, each of the plurality of pixels may include a photoelectric conversion element arranged in a first region and a well region arranged in a second region on the first region, and the well regions in the plurality of pixels may be separated by an insulating film.

In the imaging device according to the first aspect, the pixel may include a floating diffusion that accumulates the charge converted by the photoelectric conversion element and a transfer gate that transfers the charge accumulated in the floating diffusion to the pixel transistor, and the floating diffusion and the transfer gate may be arranged in the first region.

In the imaging device according to the first aspect, the pixel may include a floating diffusion that accumulates the charge converted by the photoelectric conversion element and a transfer gate that transfers the charge accumulated in the floating diffusion to the pixel transistor, and the floating diffusion and the transfer gate may be arranged in the second region.

In the imaging device according to the first aspect, each of the plurality of pixels may include a photoelectric conversion element and a well region arranged on the photoelectric conversion element and in which the pixel transistor is arranged, and the well region may be covered with a semiconductor region having a conductivity type different from a conductivity type of the well region.

In the imaging device according to the first aspect, the plurality of transistors of the pixel transistor may be provided corresponding to different pixels.

In the imaging device according to the first aspect, the pixel group may include a first region, a second region, a third region, and a fourth region arranged in a plane direction of the pixel array unit, the first region may include a first pixel group, the second region may include a second pixel group, the third region may be arranged between the first region and the second region and may include a first portion of the pixel transistor, and the fourth region may be arranged on an opposite side of the third region with the second region interposed therebetween and may include a second portion of the pixel transistor.

In the imaging device according to the first aspect, the first pixel group may include a plurality of first pixels, each of the plurality of first pixels may be separated by a first semiconductor region of a first conductivity type, the second pixel group may include a plurality of second pixels, each of the plurality of second pixels may be separated by a second semiconductor region of the first conductivity type, the first portion may be arranged in a first well region of the first conductivity type, the first well region may be separated by a third semiconductor region of a second conductivity type different from the first conductivity type, the second portion may be arranged in a second well region of the first conductivity type, and the second well region may be separated by a fourth semiconductor region of the second conductivity type.

The imaging device according to the first aspect may further include a differential amplification unit. In this imaging device, the pixel array unit may include a first pixel group including a first pixel and a second pixel group including a second pixel, and be configured such that incident light is incident on a photoelectric conversion element included in the first pixel and the incident light is not incident on a photoelectric conversion element included in the second pixel, and the differential amplification unit may cause different currents to flow in the first pixel group and the second pixel in a reset period and a readout period.

In the imaging device according to the first aspect, the pixel transistor may include a reset transistor, an amplification transistor, and a selection transistor, and the differential amplification unit may include a tail current source that causes a constant current to flow through the amplification transistor of each of the first pixel group and the second pixel group, and a current mirror circuit that causes an equal current to flow through the first pixel group and the second pixel group.

In the imaging device according to the first aspect, the differential amplification unit may further include a reset constant current circuit that causes a predetermined current to flow through the second pixel group during a reset period.

A method for driving an imaging device according to a second aspect, the imaging device including a pixel array unit arranged in a matrix in units of a pixel group including a plurality of pixels that performs photoelectric conversion, and a pixel transistor provided corresponding to each pixel group and including a plurality of transistors. The method includes controlling a substrate potential of at least one transistor of the plurality of transistors during a readout period to control a threshold voltage of the transistor.

In the method for driving the imaging device according to the second aspect, the transistor may include an n-channel transistor, and a positive pulse voltage may be applied to the transistor during the readout period.

In the method for driving the imaging device according to the second aspect, the transistor may include an n-channel transistor, and a negative pulse voltage may be applied to the transistor during the readout period.

An electronic device according to a third aspect includes an imaging device, and a signal processing unit that performs signal processing on the basis of a pixel signal imaged by the imaging device. The imaging device includes a pixel array unit arranged in a matrix in units of a pixel group including a plurality of pixels that performs photoelectric conversion, a pixel transistor provided corresponding to each pixel group and including a plurality of transistors, and a circuit that controls a threshold voltage of at least one transistor of the plurality of transistors.

### BRIEF DESCRIPTION OF DRAWINGS

FIG. 1 is a diagram illustrating a configuration of a pixel group of an imaging device according to a first embodiment.

FIG. 2 is a cross-sectional view illustrating a pixel group according to the first embodiment.

FIG. 3 is a circuit diagram of a pixel group according to the first embodiment.

FIG. 4 is a diagram illustrating a potential at the time of reading a pixel group according to the first embodiment.

FIG. 5 is an overall view illustrating the imaging device according to the first embodiment.

FIG. 6 is a diagram illustrating wiring connected to a pixel region and a selection transistor according to the first embodiment.

FIG. 7 is a diagram illustrating a pulse waveform supplied to a selection transistor of a pixel region at the time of reading according to the first embodiment.

FIG. 8 is a diagram illustrating a configuration of a pixel group of an imaging device according to a second embodiment.

FIG. 9 is a circuit diagram of a pixel group according to the second embodiment.

FIG. 10 is a diagram illustrating a potential at the time of reading a pixel group according to the second embodiment.

FIG. 11 is a diagram illustrating wiring connected to a pixel region and a reset transistor according to the second embodiment.

FIG. 12 is a diagram illustrating a pulse waveform supplied to a reset transistor of a pixel region at the time of reading according to the second embodiment.

FIG. 13 is a circuit diagram of a pixel group of an imaging device according to a third embodiment.

FIG. 14 is a diagram illustrating a potential at the time of reading a pixel group according to the third embodiment.

FIG. 15 is a diagram illustrating a pulse waveform supplied to a selection transistor in a pixel region at the time of reading according to the third embodiment.

FIG. 16 is a circuit diagram of a pixel group of an imaging device according to a fourth embodiment.

FIG. 17 is a diagram illustrating a pulse waveform supplied to a reset transistor in a pixel region at the time of reading according to the fourth embodiment.

FIG. 18 is a plan view illustrating a pixel group of an imaging device according to a fifth embodiment.

FIG. 19 is a cross-sectional view of a pixel group according to the fifth embodiment.

FIG. 20 is a plan view illustrating a pixel group of an imaging device according to a sixth embodiment.

FIG. 21 is a plan view illustrating a pixel group of an imaging device according to a seventh embodiment.

FIG. 22 is a cross-sectional view of a pixel group according to the seventh embodiment.

FIG. 23 is a circuit diagram illustrating an imaging device according to an eighth embodiment.

FIG. 24 is a block diagram illustrating an example of a schematic configuration of a vehicle control system.

FIG. 25 is an explanatory diagram illustrating an example of installation positions of an outside-vehicle information detecting section and an imaging section.

### MODES FOR CARRYING OUT THE INVENTION

First, circumstances leading to an imaging device of the present disclosure will be described. In Patent Document 1, the dynamic range is increased by increasing the area of a photodiode. However, in a case where only the saturation signal amount of the photodiode is simply increased, the voltage amplitude to be processed in the pixel transistor and the subsequent circuit block also increases. In this case, unless the dynamic range of the subsequent circuit is also further increased, the number of electrons that can be finally handled as an image, that is, the dynamic range of the imaging device does not increase. Therefore, as a result of intensive research, the inventor of the present application has found that it is sufficient to control a threshold value of a pixel transistor by adjusting a well potential applied to a well region of the pixel transistor to further increase the dynamic range. In the following embodiments of the present disclosure, an imaging device in which a well potential of a pixel transistor is adjusted will be described.

Hereinafter, embodiments of the present disclosure are described with reference to the drawings. In the embodiments to be described below, although components of an imaging device and an electronic device will be mainly described, the imaging device and the electronic device may have components and functions that are not illustrated or described. The following description does not exclude components and functions that are not illustrated or described.

Furthermore, the drawings referred to in the following description are drawings for illustrating the embodiments of the present disclosure and promoting understanding thereof, and shapes, dimensions, ratios and the like in the drawings may be different from actual ones for the sake of clarity.

### First Embodiment

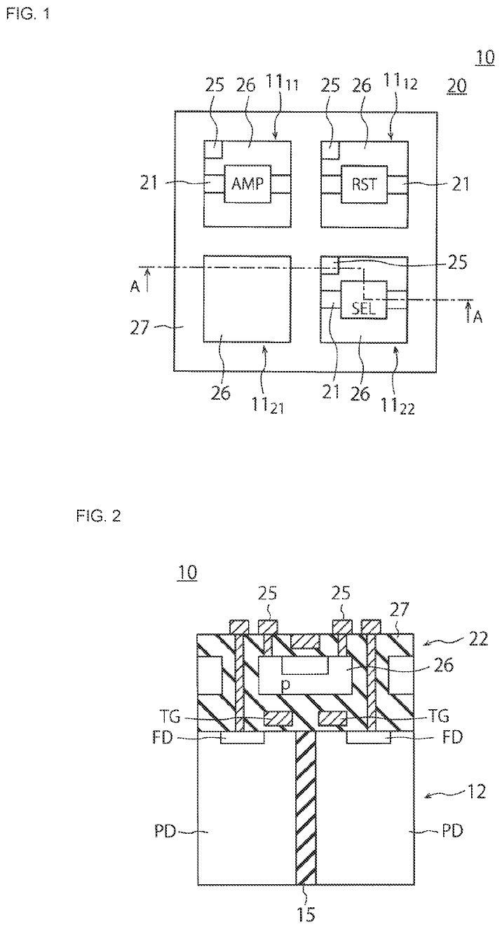

An imaging device according to a first embodiment will be described with reference to FIGS. 1 to 7. The imaging device according to the first embodiment includes a pixel group arranged in m rows and n columns, where m and n are natural numbers, and a pixel transistor provided corresponding to the pixel group. A pixel group according to the present embodiment and a pixel transistor provided corresponding to the pixel group will be described with reference to FIG. 1. As illustrated in FIG. 1, a pixel group 10 includes a plurality of (four in FIG. 1) pixels 11₁₁ to 11₂₂ arranged in an array, and each of the pixels 11₁₁ to 11₂₂ includes a photoelectric conversion element (photodiode) PD. The photodiode FD includes, for example, silicon.

As illustrated in FIG. 2, these photoelectric conversion elements PD are arranged in a semiconductor layer 12, and a pixel transistor is arranged in an upper layer 22 of the semiconductor layer 12. FIG. 2 is a cross-sectional view taken along a cutting line A-A illustrated in FIG. 1. As illustrated in FIG. 2, the adjacent photodiodes PD are insulated by an insulating film 15 embedded in a trench. Note that in FIG. 2, a pixel transistor is formed in the pixel 11₂₁, too.

A pixel transistor 20 includes a reset transistor RST, an amplification transistor AMP, and a selection transistor SEL. Each of these transistors is an n-channel transistor and is formed in a p-well region 26, and each source region and drain region 21 is an n⁺ region. Each pixel transistor is formed in the p-well region 26. The reset transistor RST is arranged on the pixel 11₁₁, the amplification transistor AMP is arranged on the pixel 11₁₂, and the selection transistor SEL is arranged on the pixel 11₂₂. Note that in FIG. 1, in each pixel 11ᵢⱼ (i, j=1, 2), a region (p-well region) in which the pixel transistor is formed is insulated and separated by an insulating film (for example, silicon oxide film) 27. However, the pixels 11₁₁, 11₁₂, and 11₂₁ other than the pixel 11₂₂ in which the selection transistor SEL is formed do not necessarily have to be separated by the insulating film 27.

Furthermore, as illustrated in FIG. 1, a terminal (pad) 25 for adjusting a substrate potential of the pixel transistor is provided in each of regions (p-well) 26 on the pixel in which the pixel transistors are provided. The terminal 25 includes a p⁺ region having a p-type impurity concentration higher than that of the p-well region. Note that while there are two terminals 25 in FIG. 2, the number of terminals may be one as illustrated in FIG. 1.

Furthermore, each of the pixels 11ᵢⱼ (i, j=1, 2) is provided with a floating diffusion FD that accumulates signal charge from the photodiode PD, and the photodiode PD and the floating diffusion FD are connected by a transfer gate TG.

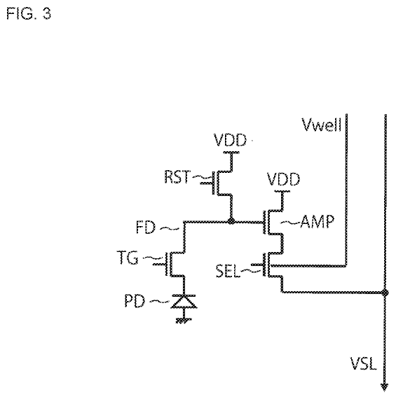

FIG. 3 illustrates a circuit diagram of the pixel group 10 configured as described above. As can be seen from FIG. 3, in the pixels 11₁₁ to 11₂₂, each photoelectric conversion element FD is connected to the floating diffusion FD via the transfer gate TG. Note that in FIG. 3, the photoelectric conversion elements FD and the transfer gates TG of the four pixels are both collectively displayed as one component. This floating diffusion FD is connected to a power supply VDD via the reset transistor RST, and is also connected to a gate of the amplification transistor AMP. This amplification transistor AMP has a drain connected to the power supply VDD and the drain thereof connected to a source of the selection transistor SEL. That is, the amplification transistor AMP is a source follower amplifier. Note that in the present embodiment, Vwell is applied to the substrate potential adjustment terminal 25 of the selection transistor SEL, and VSS is applied to the substrate potential adjustment terminal 25 of each of the reset transistor RST and the amplification transistor AMP.

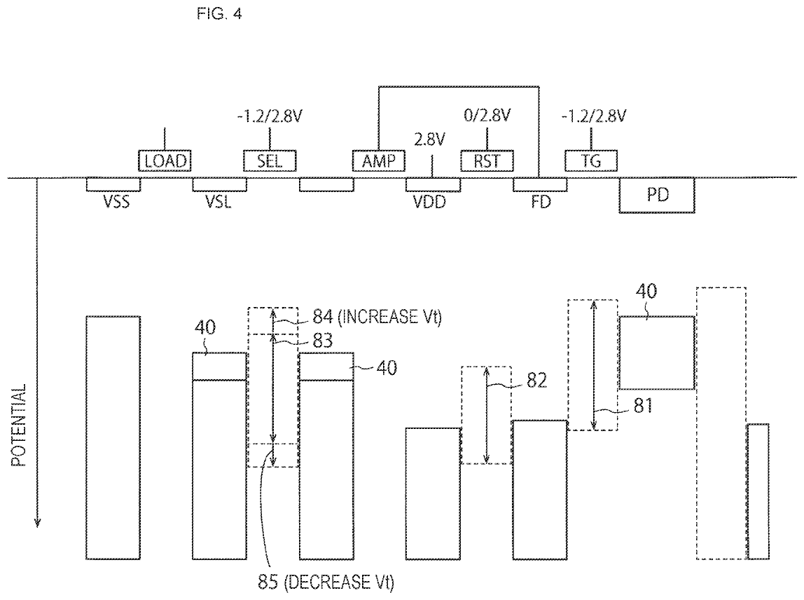

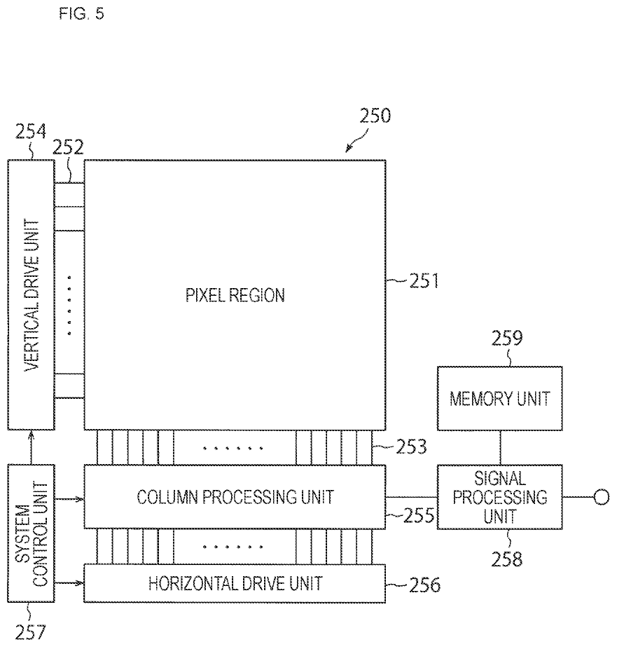

A read operation in the pixel configured as described above will be described with reference to FIG. 4. FIG. 4 illustrates potentials of the transfer gate TG and the pixel transistors SEL and RSL in the read operation of the imaging device according to the present embodiment. When exposure is completed, signal charge 40 is accumulated in the photoelectric conversion element PD. At this time, when a transfer pulse having a width of −1.2 V to 2.8 V, for example, is supplied to the transfer gate TG, the potential of the transfer gate TG fluctuates in a range of an arrow 81. Due to this potential fluctuation, the signal charge 40 flows into the floating diffusion FD. A potential of −1.2 V is a potential at which the transfer gate TG is turned off, and a potential of 2.8 V is a potential at which the transfer gate TG is turned on. Note that noise charge is accumulated in the floating diffusion FD during the exposure period. At this time, a reset pulse is applied to the gates of the reset transistors RST of the pixels of the selected row. This reset pulse is in the range of 0 V to 2.8 V. A potential of 0 V is a potential at which the reset transistor RST is turned off, and a potential of 2.8 V is a potential at which the reset transistor RST is turned on. How much signal can be stored in the floating diffusion FD is determined by the height of the potential wall of the reset transistor RST. When a reset pulse is applied to the reset transistor RST, the potential of the reset transistor RSL fluctuates as indicated by an arrow 82 as illustrated in FIG. 4. As a result, noise charge is discharged from the floating diffusion FD, and the floating diffusion FD is reset to a potential VDD. Further, when a row selection pulse (for example, range of −1.2 V to 2.8 V) is applied to the gate of the selection transistor SEL, the potential of the selection transistor SEL fluctuates as indicated by an arrow 83. Then, the source follower amplifier AMP is in a conductive state, and the potential of the reset floating diffusion FD is output from the source follower amplifier AMP. Subsequently, a read pulse is applied from a vertical drive unit 254 (FIG. 5) described later to the transfer gate TG of the pixel of the selected row, the signal charge 40 of the photoelectric conversion element PD is transferred to the floating diffusion FD, and the potential of the floating diffusion FD decreases. Subsequently, the charge of the floating diffusion FD in which the signal charge is accumulated is output from the source follower amplifier AMP. In the next step, a difference between the reset output and the output due to the signal charge is obtained by, for example, correlated double sampling. In the final step, the signal charge in the floating diffusion FD is reset, and the read operation is completed. At this time, in the present embodiment, the substrate potential Vwell of the selection transistor SEL is adjusted via the terminal 25. When the substrate potential Vwell is set to a low potential with respect to the gate, the source, and the drain of the selection transistor SEL, a threshold voltage Vt of the selection transistor SEL increases as indicated by an arrow 84, and the selection transistor SEL is hardly turned on. Conversely, when the substrate potential Vwell is set to a high potential with respect to the gate, the source, and the drain of the selection transistor SEL, the threshold voltage Vt of the selection transistor SEL decreases as indicated by an arrow 85, and the selection transistor SEL is easily turned on. Note that in the present embodiment, at the time of reading, the potential Vwell is applied to the substrate potential adjustment terminal 25 of the selection transistor SEL, and the potential VSS is applied to the substrate potential adjustment terminal 25 of the reset transistor RST and the amplification transistor AMP.

As described above, by adjusting the substrate potential of the selection transistor SEL at the time of reading, it is possible to expand the range of signals that can be handled without affecting the signal level. That is, the dynamic range can be increased easily.

Next, FIG. 5 illustrates an overall configuration of the imaging device according to the first embodiment. An imaging device 250 according to the present embodiment is, for example, a back-side illumination image sensor 250, and includes a pixel region 251, a pixel drive line 252, a vertical signal line 253, a vertical drive unit 254, a column processing unit 255, a horizontal drive unit 256, a system control unit 257, a signal processing unit 258, and a memory unit 259. These are formed on a semiconductor substrate (chip) such as a silicon substrate (not illustrated). Note that the pixel region 251 may be formed on a sensor chip including a first semiconductor substrate, the pixel drive line 252, the vertical signal line 253, the vertical drive unit 254, the column processing unit 255, the horizontal drive unit 256, the system control unit 257, the signal processing unit 258, and the memory unit 259 may be formed on a circuit chip including a second semiconductor substrate, and these chips may be bonded to each other.

A pixel region 251 is a pixel array in which the pixels are two-dimensionally arranged, and converts an optical signal into an electric signal to perform imaging. In the pixel region 251, with respect to pixels, the pixel drive line 252 is provided for every two rows, and the vertical signal line 253 is provided for every two columns. In the present embodiment, the configuration of the pixels constituting the pixel region 251 will be described in detail later.

The vertical drive unit 254 includes a shift register, an address decoder, and the like, and supplies a drive signal to the pixel drive line 252 such that a pixel signal corresponding to charge accumulated in each of imaging elements in the pixel region 251 is read row by row from the top, in order of an odd column and an even column.

The column processing unit 255 includes a signal processing circuit for every two columns of the pixels of the pixel region 251. Each signal processing circuit of the column processing unit 255 performs signal processing, such as A/D conversion processing or correlated double sampling (CDS) processing, on the pixel signal read from the corresponding pixel and supplied through the vertical signal line 253. The column processing unit 255 temporarily holds the pixel signal subjected to the signal processing.

The horizontal drive unit 256 includes a shift register, an address decoder, and the like, and sequentially selects the signal processing circuits of the column processing unit 255. Accordingly, the pixel signals subjected to the signal processing by the signal processing circuits of the column processing unit 255 are sequentially output to the signal processing unit 258.

The system control unit 257 includes a timing generator or the like that generates various timing signals, and controls the vertical drive unit 254, the column processing unit 255, and the horizontal drive unit 256 on the basis of the various timing signals generated by the timing generator.

The signal processing unit 258 performs various kinds of signal processing on the pixel signal output from the column processing unit. At this time, the signal processing unit 258 stores, in the memory unit 259, an intermediate result or the like of the signal processing, as necessary, and refers to the result at a necessary timing. The signal processing unit 258 outputs the pixel signal subjected to the signal processing.

The memory unit 259 includes a dynamic random access memory (DRAM), a static random access memory (SRAM), and the like.

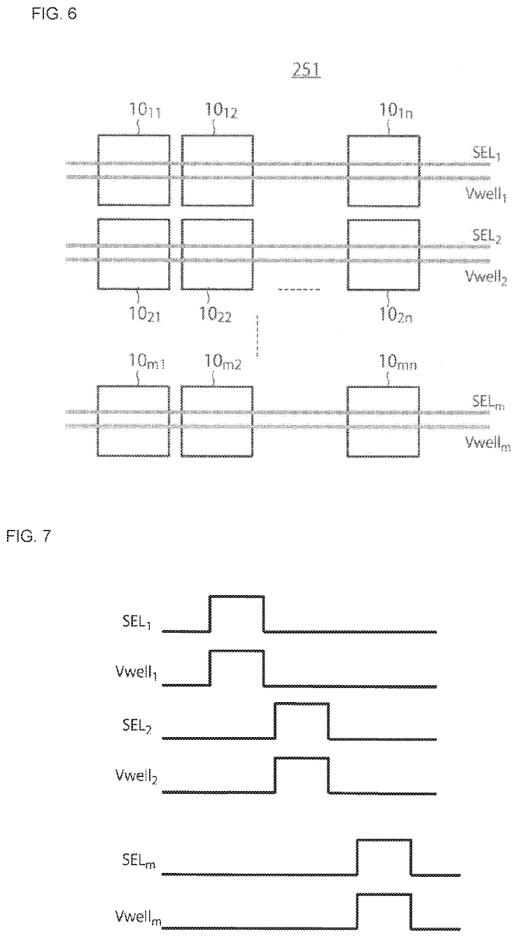

In the pixel region 251 of the imaging device according to the first embodiment, a plurality of two-dimensionally arranged pixels is divided into pixel groups having pixels arranged in two rows and two columns. For example, as illustrated in FIG. 6, the pixel region 251 includes pixel groups 10₁₁ to 10ₘₙ arranged in m rows and n columns where m and n are natural numbers. Each pixel group 10ᵢⱼ (i=1, . . . , m, j 32 1, . . . , n) includes the pixels 11₁₁ to 11₂₂ arranged in two rows and two columns illustrated in FIG. 1.

In the first embodiment, the substrate potential Vwell is supplied from the vertical drive unit 254 illustrated in FIG. 5 to the selection transistor SEL of the pixel via the pixel drive line 252. Therefore, as illustrated in FIG. 6, in the selection transistor SEL of the pixel in the pixel groups 10ᵢ₁ to 10ᵢₙ of the i-th (i=1, . . . , m) row, a wiring Vwellᵢ that supplies the substrate potential Vwell is provided in addition to a wiring SELᵢ connected to the gate of the selection transistor SEL. That is, a pulse for turning on the selection transistors SEL and a pulse for adjusting the substrate potential of the selection transistors SEL are simultaneously applied to the selection transistors SEL of the pixels in the pixel groups of the same row. These pulse waveforms are illustrated in FIG. 7. Note that the wiring SELᵢ (i=1, . . . , m) and the wiring Vwellᵢ are connected to the vertical drive unit 254 via the pixel drive line 252.

The pulse supplied to the wiring SELᵢ of the i-th (i=1, . . . , m) row and the pulse supplied to the wiring VWllᵢ are sequentially applied from the first row to the m-th row as illustrated in FIG. 7, and the read operation is performed. The on-timing (rising timing) and the off-timing (falling timing) of the pulse supplied to the wiring SELᵢ (i=1, . . . , m) and the pulse supplied to the wiring VWllᵢ are preferably the same. In a case where the on-timings of the pulse supplied to the wiring SELᵢ (i=1, . . . , m) and the pulse supplied to the wiring VWllᵢ overlap with the off-timings in the previous read operation, or the off-timings of the pulse supplied to the wiring SELᵢ (i=1, . . . , m) and the pulse supplied to the wiring VWllᵢ overlap with the on-timings in the previous read operation, the read currents become mixed up, and therefore it is preferable to avoid such a case.

Furthermore, the larger the amplitude of the pulse supplied to the wiring Vwellᵢ (i=1, . . . , m), the greater the effect of controlling the threshold voltage Vt. However, in a case where the amplitude is increased, the delay of the pulse signal increases and the power consumption increases. Therefore, the amplitude is determined in consideration of the necessary control amount of the threshold voltage Vt, the delay time, and the power consumption.

Note that if the potential Vwell supplied to the well region or the like of the selection transistor SEL is kept high, the effect when the selection transistor SEL is turned off cannot be obtained, and the leak current increases. When the selection transistor SEL is turned off, it is preferable to lower the potential of the well region after the timing at which the selection transistor SEL and the reset transistor RST are turned off.

Furthermore, in the present embodiment, each pixel group has pixels arranged in two rows and two columns. However, a pixel group may include pixels arranged in two rows and four columns, or a pixel group may include one pixel. Moreover, two or more selection transistors may be arranged in each pixel group. In these cases, too, there is no change in the amplitude of a signal VSL (see FIG. 3) output from the pixel, and the same analog circuit as that of the present embodiment can be used as the analog circuit in the subsequent stage.

As described above, according to the present embodiment, the substrate potential of the selection transistor SEL included in the pixel group can be adjusted at the time of reading, and the dynamic range can be increased easily.

### Second Embodiment

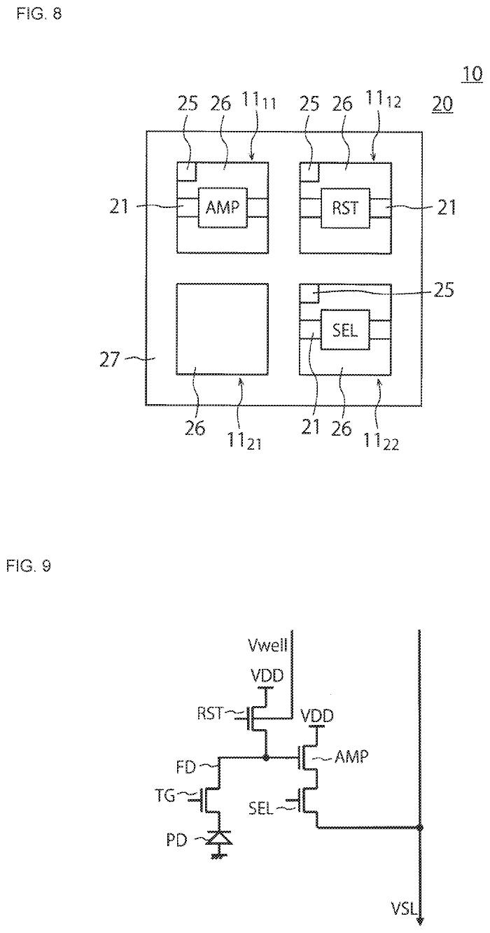

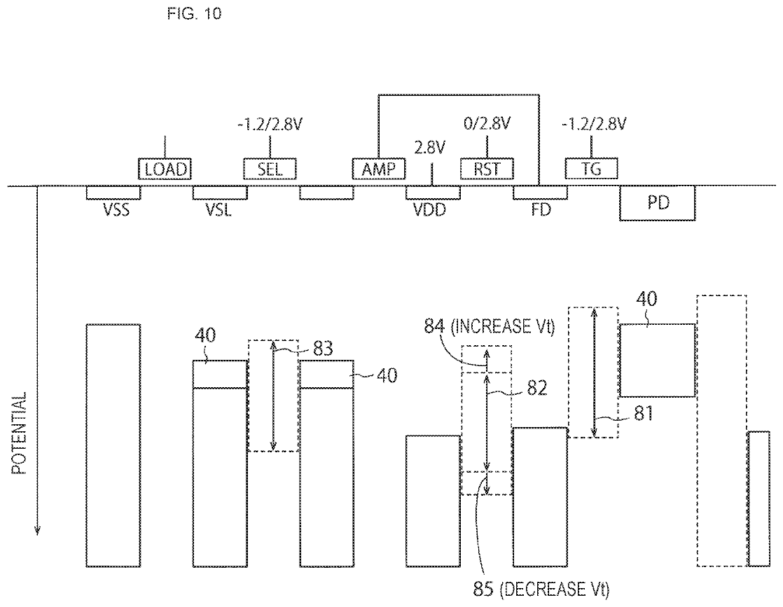

An imaging device according to a second embodiment will be described with reference to FIGS. 8 to FIG. 12. The imaging device according to the second embodiment has the same configuration as the imaging device of the first embodiment except that the pixel transistor for adjusting the substrate potential is a reset transistor RST. FIG. 8 illustrates a configuration of a pixel group of the imaging device according to the second embodiment, FIG. 9 illustrates a circuit diagram of a pixel transistor of the pixel group, and FIG. 10 illustrates a potential diagram at the time of reading the pixel group.

As can be seen from FIGS. 8 and 9, similarly to the case of the first embodiment, the reset transistor RST, an amplification transistor AMP, a selection transistor SEL, and a transfer gate TG constituting the pixel transistor are n-channel transistors, and a potential Vwell for adjusting the substrate potential is supplied to the reset transistor RST. That is, a potential VSS is applied to a substrate potential adjustment terminal 25 of the amplification transistor AMP and the selection transistor SEL illustrated in FIG. 8, and the potential Vwell is supplied to the substrate potential adjustment terminal 25 of the reset transistor RST.

Next, a read operation of the imaging device according to the second embodiment will be described with reference to FIG. 10. FIG. 10 illustrates potentials of the transfer gate TG and the pixel transistors SEL and RSL in the read operation of the imaging device according to the second embodiment. When exposure is completed, signal charge 40 is accumulated in the photoelectric conversion element PD. At this time, when a transfer pulse having a width of −1.2 V to 2.8 V, for example, is supplied to the transfer gate TG, the potential of the transfer gate TG fluctuates in a range of an arrow 81. As a result, the signal charge 40 flows into a floating diffusion FD. A potential of −1.2 V is a potential at which the transfer gate TG is turned off, and a potential of 2.8 V is a potential at which the transfer gate TG is turned on. Note that the floating diffusion FD has noise charge accumulated during the exposure period. At this time, a reset pulse is applied to the gates of the reset transistors RST of the pixels of the selected row. This reset pulse is in the range of 0 V to 2.8 V. A potential of 0 V is a potential at which the reset transistor RST is turned off, and a potential of 2.8 V is a potential at which the reset transistor RST is turned on. When a reset pulse is applied to the reset transistor RST, the potential of the reset transistor RSL fluctuates as indicated by an arrow 82 as illustrated in FIG. 10. As a result, noise charge is discharged from the floating diffusion FD, and the floating diffusion FD is reset to a potential VDD. Further, when a row selection pulse (for example, range of −1.2 V to 2.8 V) is applied to the gate of the selection transistor SEL, the potential of the selection transistor SEL fluctuates as indicated by an arrow 83. Then, the source follower amplifier AMP is in a conductive state, and the potential of the reset floating diffusion FD is output from the source follower amplifier AMP. Subsequently, a read pulse is applied from a vertical drive unit 254 (FIG. 5) described later to the transfer gate TG of the pixel of the selected row, the signal charge 40 of the photoelectric conversion element PD is transferred to the floating diffusion FD, and the potential of the floating diffusion FD decreases. Subsequently, the charge of the floating diffusion FD in which the signal charge is accumulated is output from the source follower amplifier AMP. In the next step, a difference between the reset output and the output due to the signal charge is obtained by, for example, correlated double sampling. In the final step, the signal charge in the floating diffusion FD is reset, and the read operation is completed. At this time, in the present embodiment, the substrate potential Vwell of the reset transistor RST is adjusted via the terminal 25. When the substrate potential Vwell is set to a low potential with respect to the gate, the source, and the drain of the reset transistor RST, a threshold voltage Vt of the reset transistor RST increases as indicated by an arrow 84, and the reset transistor RST is hardly turned on. Conversely, when the substrate potential Vwell is set to a high potential with respect to the gate, the source, and the drain of the reset transistor RST, the threshold voltage Vt of the reset transistor RST decreases as indicated by an arrow 85, and the reset transistor RST is easily turned on.

As described above, by adjusting the substrate potential of the reset transistor RST at the time of reading, it is possible to expand the range of signals that can be handled without affecting the signal level. That is, the dynamic range can be increased easily.

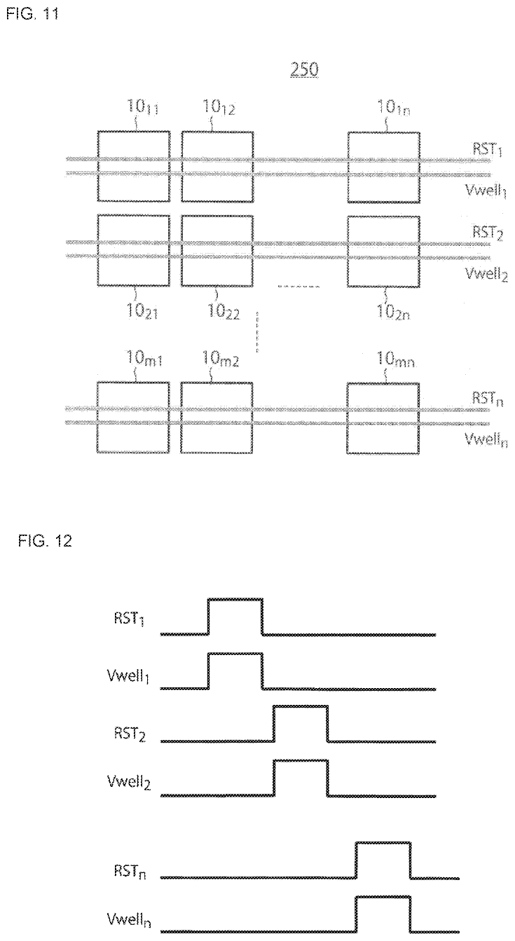

In the second embodiment, the substrate potential Vwell is supplied from the vertical drive unit 254 illustrated in FIG. 5 to the reset transistor RST of the pixel via a pixel drive line 252. Therefore, as illustrated in FIG. 11, in the reset transistor RST of the pixel in pixel groups 10ᵢ₁ to 10ᵢₙ of the i-th (i=1, . . . , m) row, a wiring Vwellᵢ that supplies the substrate potential Vwell is provided in addition to a wiring RSTᵢ connected to the gate of the reset transistor RST. That is, a pulse for turning on the reset transistors RST and a pulse for adjusting the substrate potential of the reset transistors RST are simultaneously applied to the reset transistors RST of the pixels in the pixel groups of the same row. These pulse waveforms are illustrated in FIG. 12. The wiring RSTᵢ (i=1, . . . , m) and the wiring Vwellᵢ are connected to the vertical drive unit 254 via the pixel drive line 252 illustrated in FIG. 5.

The pulse supplied to the wiring RSTᵢ of the i-th (i=1, . . . , m) row and the pulse supplied to the wiring VWllᵢ are sequentially applied from the first row to the m-th row as illustrated in FIG. 12, and the read operation is performed. The on-timing (rising timing) and the off-timing (falling timing) of the pulse supplied to the wiring RSTᵢ (i=1, . . . , m) and the pulse supplied to the wiring VWllᵢ are preferably the same. In a case where the on-timings of the pulse supplied to the wiring RSTᵢ (i=1, . . . , m) and the pulse supplied to the wiring VWllᵢ overlap with the off-timings in the previous read operation, or the off-timings of the pulse supplied to the wiring RSTᵢ (i=1, . . . , m) and the pulse supplied to the wiring VWlli overlap with the on-timings in the previous read operation, the read currents become mixed up, and therefore it is preferable to avoid such a case.

Furthermore, as in the case of the first embodiment, the larger the amplitude of the pulse supplied to the wiring Vwellᵢ (i=1, . . . , m), the greater the effect of controlling the threshold voltage Vt. However, in a case where the amplitude is increased, the delay of the pulse signal increases and the power consumption increases. Therefore, the amplitude is determined in consideration of the necessary control amount of the threshold voltage Vt, the delay time, and the power consumption.

Furthermore, in the second embodiment, each pixel group has pixels arranged in two rows and two columns. However, a pixel group may include pixels arranged in two rows and four columns, or a pixel group may include one pixel. Moreover, two or more selection transistors may be arranged in each pixel group. In these cases, too, there is no change in the amplitude of a signal VSL (see FIG. 3) output from the pixel, and the same analog circuit as that of the present embodiment can be used as the analog circuit in the subsequent stage.

As described above, according to the second embodiment, the substrate potential of the reset transistor RST included in the pixel group can be adjusted at the time of reading, and the dynamic range can be increased easily.

Note that in the imaging device according to the second embodiment, as in the imaging device according to the first embodiment, the adjustment potential Vwell may be supplied to the substrate potential adjustment terminal 25 of the selection transistor SEL of each pixel group at the time of the read operation. That is, the substrate potentials of the selection transistor SEL and the reset transistor RST of each pixel group may be adjusted at the time of reading. As described above, in a case where the substrate potentials of the selection transistor SEL and the reset transistor RST are adjusted together, if it is desired to control the threshold voltages of the reset transistor RST and the selection transistor SEL by the same amount, it is sufficient that the same potential level Vwell is supplied to both well regions. For example, normally, in a case where it is desired to control the threshold voltage Vt of the reset transistor RST and the selection transistor at 0 V in the well region, a potential Vwell of about 0.5 V is supplied to each well region. As a result, the threshold voltages of the reset transistor RST and the selection transistor SEL change by about 0.2 V.

Note that the voltages applied to the gates of the reset transistor RST and the selection transistor SEL are different from each other, and there is no correlation between the gate voltages and the potential Vwell supplied to the well region.

### Third Embodiment

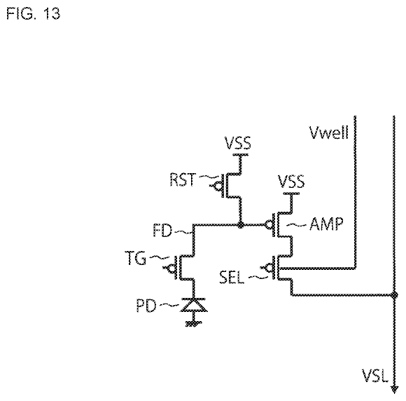

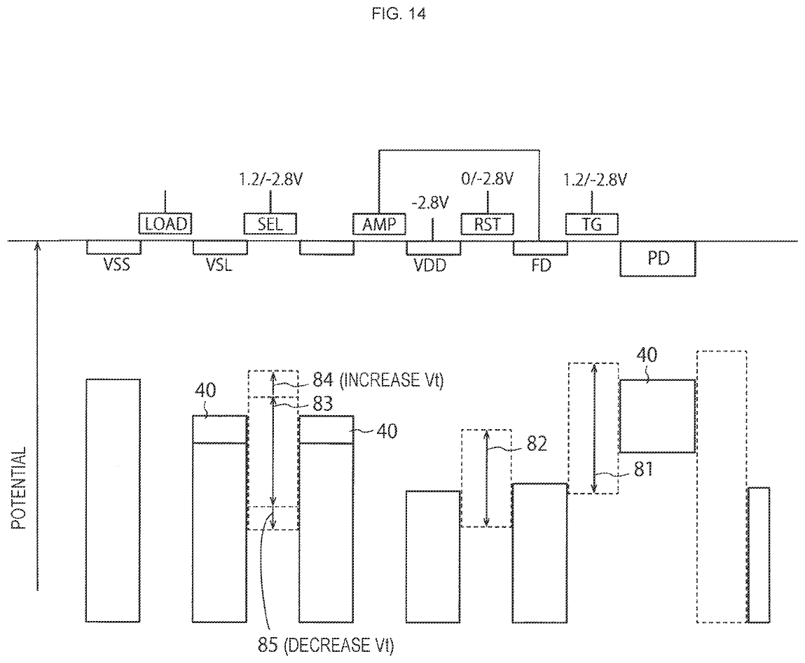

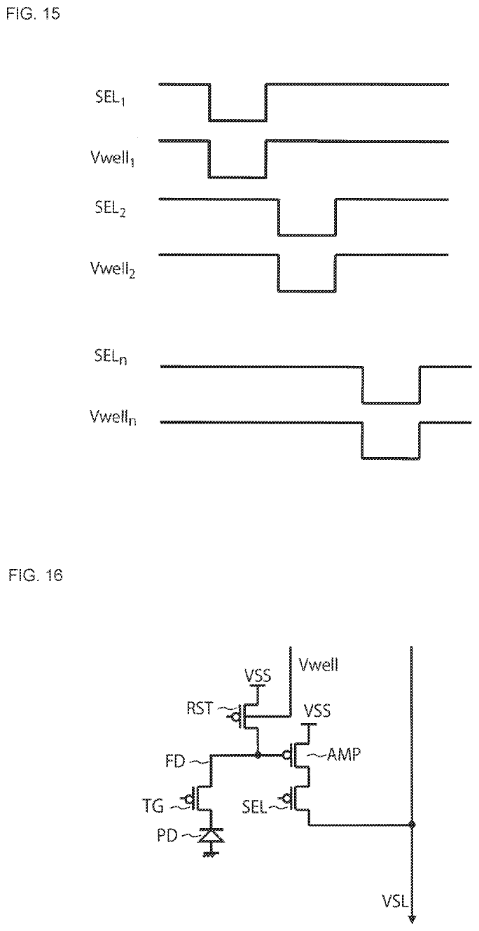

An imaging device according to a third embodiment will be described with reference to FIGS. 13 to 15. FIG. 13 illustrates a circuit diagram of a pixel transistor of a pixel group of the imaging device according to the third embodiment, FIG. 14 illustrates a potential diagram at the time of a read operation of the pixel group, and FIG. 15 illustrates a waveform diagram at the time of reading supplied to a selection transistor SEL of the pixel group. As illustrated in FIG. 13, the imaging device according to the third embodiment is different from the first embodiment in that a reset transistor RST, an amplification transistor AMP, the selection transistor SEL, and a transfer gate TG constituting a pixel transistor are p-channel transistors, and a potential Vwell for adjusting a substrate potential is supplied to the selection transistor SEL. Note, however, that the potential Vwell is a negative potential. Note that a potential VSS is applied as the substrate potentials of the amplification transistor AMP and the reset transistor RST.

Next, a read operation of the imaging device according to the third embodiment will be described with reference to FIG. 14. FIG. 13 illustrates potentials of the transfer gate TG and the pixel transistors SEL and RSL in the read operation of the imaging device according to the third embodiment. When exposure is completed, signal charge 40 is accumulated in the photoelectric conversion element PD. At this time, when a transfer pulse having a width of 1.2 V to −2.8 V, for example, is supplied to the transfer gate TG, the potential of the transfer gate TG fluctuates in a range of an arrow 81. As a result, the signal charge 40 flows into a floating diffusion FD. A potential of 1.2 V is a potential at which the transfer gate TG is turned off, and a potential of −2.8 V is a potential at which the transfer gate TG is turned on. Note that the floating diffusion FD has noise charge accumulated during the exposure period. At this time, a reset pulse is applied to the gates of the reset transistors RST of the pixels of the selected row. This reset pulse is in the range of 0 V to −2.8 V. A potential of 0 V is a potential at which the reset transistor RST is turned off, and a potential of −2.8 V is a potential at which the reset transistor RST is turned on. When a reset pulse is applied to the reset transistor RST, the potential of the reset transistor RSL fluctuates as indicated by an arrow 82 as illustrated in FIG. 14. As a result, noise charge is discharged from the floating diffusion FD, and the floating diffusion FD is reset to a potential VDD. Further, when a row selection pulse (for example, range of 1.2 V to −2.8 V) is applied to the gate of the selection transistor SEL, the potential of the selection transistor SEL fluctuates as indicated by an arrow 83. Then, the source follower amplifier AMP is in a conductive state, and the potential of the reset floating diffusion FD is output from the source follower amplifier AMP. Subsequently, a read pulse is applied from a vertical drive unit 254 (FIG. 5) described later to the transfer gate TG of the pixel of the selected row, the signal charge 40 of the photoelectric conversion element PD is transferred to the floating diffusion FD, and the potential of the floating diffusion FD decreases. Subsequently, the charge of the floating diffusion FD in which the signal charge is accumulated is output from the source follower amplifier AMP. In the next step, a difference between the reset output and the output due to the signal charge is obtained by, for example, correlated double sampling. In the final step, the signal charge in the floating diffusion FD is reset, and the read operation is completed. At this time, in the present embodiment, the substrate potential Vwell of the selection transistor SEL is adjusted via a substrate potential adjustment terminal (not illustrated). When the substrate potential Vwell is set to a low potential with respect to the gate, the source, and the drain of the selection transistor SEL, a threshold voltage Vt of the selection transistor SEL increases as indicated by an arrow 84, and the selection transistor RST is hardly turned on. Conversely, when the substrate potential Vwell is set to a high potential with respect to the gate, the source, and the drain of the selection transistor SEL, the threshold voltage Vt of the selection transistor SEL decreases as indicated by an arrow 85, and the selection transistor SEL is easily turned on.

As described above, by adjusting the substrate potential of the selection transistor SEL at the time of reading, it is possible to expand the range of signals that can be handled without affecting the signal level. That is, the dynamic range can be increased easily.

In the third embodiment, the substrate potential Vwell is supplied from the vertical drive unit 254 illustrated in FIG. 5 to the pixel selection transistor SEL via a pixel drive line 252. Therefore, as in the case of the first embodiment, in the selection transistor SEL of the pixel in pixel groups 10ᵢ₁ to 10ᵢₙ of the i-th (i=1, . . . , m) row, a wiring Vwellᵢ that supplies the substrate potential Vwell is provided in addition to a wiring SELᵢ connected to the gate of the selection transistor SEL. That is, a pulse for turning on the selection transistors SEL and a pulse for adjusting the substrate potential of the selection transistors SEL are simultaneously applied to the selection transistors SEL of the pixels in the pixel groups of the same row. These pulse waveforms are illustrated in FIG. 14. The wiring SELᵢ (i=1, . . . , m) and the wiring Vwellᵢ are connected to the vertical drive unit 254 via the pixel drive line 252.

The pulse supplied to the wiring SELᵢ of the i-th (i=1, . . . , m) row and the pulse supplied to the wiring VWllᵢ are sequentially applied from the first row to the m-th row as illustrated in FIG. 15, and the read operation is performed. The on-timing (rising timing) and the off-timing (falling timing) of the pulse supplied to the wiring SELᵢ (i=1, . . ., m) and the pulse supplied to the wiring VWllᵢ are preferably the same. In a case where the on-timings of the pulse supplied to the wiring SELᵢ (i=1, . . . , m) and the pulse supplied to the wiring VWllᵢ overlap with the off-timings in the previous read operation, or the off-timings of the pulse supplied to the wiring SELᵢ (i=1, . . . , m) and the pulse supplied to the wiring VWllᵢ overlap with the on-timings in the previous read operation, the read currents become mixed up, and therefore it is preferable to avoid such a case.

Furthermore, as in the case of the first embodiment, the larger the amplitude of the pulse supplied to the wiring Vwellᵢ (i=1, . . . , m), the greater the effect of controlling the threshold voltage Vt. However, in a case where the amplitude is increased, the delay of the pulse signal increases and the power consumption increases. Therefore, the amplitude is determined in consideration of the necessary control amount of the threshold voltage Vt, the delay time, and the power consumption.

Furthermore, in the third embodiment, each pixel group has pixels arranged in two rows and two columns. However, a pixel group may include pixels arranged in two rows and four columns, or a pixel group may include one pixel. Moreover, two or more selection transistors may be arranged in each pixel group. In these cases, too, there is no change in the amplitude of a signal VSL (see FIG. 3) output from the pixel, and the same analog circuit as that of the present embodiment can be used as the analog circuit in the subsequent stage.

As described above, according to the third embodiment, the substrate potential of the reset transistor RST included in the pixel group can be adjusted at the time of reading, and the dynamic range can be increased easily.

### Fourth Embodiment

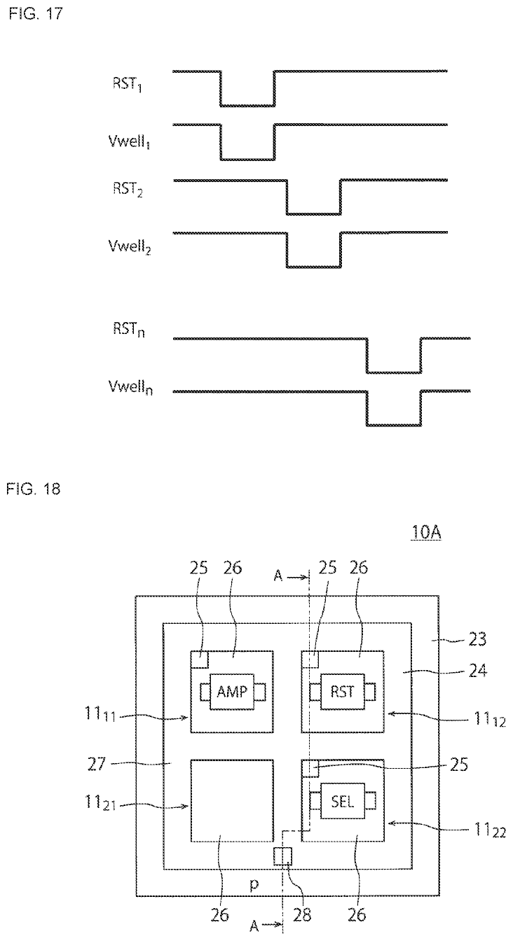

An imaging device according to a fourth embodiment will be described with reference to FIGS. 16 and 17. The imaging device according to the fourth embodiment has the same configuration as the imaging device of the third embodiment except that the pixel transistor for adjusting the substrate potential is a reset transistor RST. FIG. 16 illustrates a circuit diagram of a pixel transistor of a pixel group, and FIG. 117 illustrates a waveform diagram at the time of reading the reset transistor RST of the pixel group.

As can be seen from FIG. 16, similarly to the case of the first embodiment, the reset transistor RST, an amplification transistor AMP, a selection transistor SEL, and a transfer gate TG constituting the pixel transistor are p-channel transistors, and a potential Vwell for adjusting the substrate potential is supplied to the reset transistor RST. That is, the potential VSS is applied to a substrate potential adjustment terminal (not illustrated) of the amplification transistor AMP and the selection transistor SEL illustrated in FIG. 16, and the potential Vwell is supplied to the substrate potential adjustment terminal of the reset transistor RST.

Next, the read operation of the imaging device according to the third embodiment is performed similarly to the third embodiment. Note, however, that in the fourth embodiment, the potential Vwell for adjusting the substrate potential is supplied to the reset transistor RST at the time of the read operation. VSS is supplied as the substrate potentials of the amplification transistor AMP and the selection transistor SEL.

As described above, by adjusting the substrate potential of the reset transistor RST at the time of reading, it is possible to expand the range of signals that can be handled without affecting the signal level. That is, the dynamic range can be increased easily.

In the third embodiment, the substrate potential Vwell is supplied from a vertical drive unit 254 illustrated in FIG. 5 to the reset transistor RST of the pixel via a pixel drive line 252. Therefore, as illustrated in FIG. 11, in the reset transistor RST of the pixel in pixel groups 10ᵢ₁ to 10ᵢₙ of the i-th (i=1, . . . , m) row, a wiring Vwellᵢ that supplies the substrate potential Vwell is provided in addition to a wiring RSTᵢ connected to the gate of the reset transistor RST. That is, a pulse for turning on the reset transistors RST and a pulse for adjusting the substrate potential of the reset transistors RST are simultaneously applied to the reset transistors RST of the pixels in the pixel groups of the same row. These pulse waveforms are illustrated in FIG. 12.

The pulse supplied to the wiring RSTᵢ of the i-th (i=1, . . . , m) row and the pulse supplied to the wiring VWlli are sequentially applied from the first row to the m-th row as illustrated in FIG. 12, and the read operation is performed. The on-timing (rising timing) and the off-timing (falling timing) of the pulse supplied to the wiring RSTᵢ (i=1, . . . , m) and the pulse supplied to the wiring VWllᵢ are preferably the same. In a case where the on-timings of the pulse supplied to the wiring RSTᵢ (i=1, . . . , m) and the pulse supplied to the wiring VWllᵢ overlap with the off-timings in the previous read operation, or the off-timings of the pulse supplied to the wiring RSTᵢ (i=1, . . . , m) and the pulse supplied to the wiring VWllᵢ overlap with the on-timings in the previous read operation, the read currents become mixed up, and therefore it is preferable to avoid such a case.

Furthermore, as in the case of the first embodiment, the larger the amplitude of the pulse supplied to the wiring Vwellᵢ (i=1, . . . , m), the greater the effect of controlling the threshold voltage Vt. However, in a case where the amplitude is increased, the delay of the pulse signal increases and the power consumption increases. Therefore, the amplitude is determined in consideration of the necessary control amount of the threshold voltage Vt, the delay time, and the power consumption.

Furthermore, in the fourth embodiment, each pixel group has pixels arranged in two rows and two columns. However, a pixel group may include pixels arranged in two rows and four columns, or a pixel group may include one pixel. Moreover, two or more selection transistors may be arranged in each pixel group. In these cases, too, there is no change in the amplitude of a signal VSL (see FIG. 3) output from the pixel, and the same analog circuit as that of the present embodiment can be used as the analog circuit in the subsequent stage.

As described above, according to the fourth embodiment, the substrate potential of the reset transistor RST included in the pixel group can be adjusted at the time of reading, and the dynamic range can be increased easily.

Note that in the imaging device according to the fourth embodiment, as in the imaging device according to the third embodiment, the adjustment potential Vwell may be supplied to a substrate potential adjustment terminal 25 of the selection transistor SEL of each pixel group at the time of the read operation. That is, the substrate potentials of the selection transistor SEL and the reset transistor RST of each pixel group may be adjusted at the time of reading.

### Fifth Embodiment

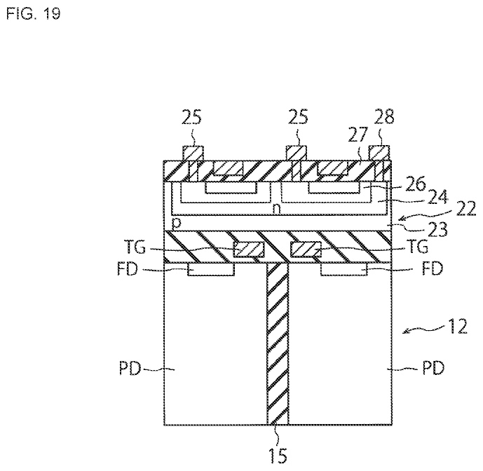

An imaging device according to a fifth embodiment will be described with reference to FIGS. 18 and 19. FIG. 18 is a plan view illustrating a pixel group of the imaging device according to the fifth embodiment, and FIG. 19 is a cross-sectional view taken along a cutting line A-A illustrated in FIG. 18. The imaging device according to the fifth embodiment has a configuration of the imaging device according to the first embodiment, in which the pixel group 10 illustrated in FIG. 1 is replaced by a pixel group 10A illustrated in FIG. 18. As in the case of the pixel group 10, the pixel group 10A includes pixels 11₁₁ to 11₂₂ arranged in two rows and two columns.

In the first to fourth embodiments, the well region 26 of the pixels 11₁₁ to 11₂₂ is insulated and separated by the insulating film 27, but in the fifth embodiment, the pixels 11₁₁ to 11₂₂ are separated using a PN junction as illustrated in FIGS. 18 and 19. That is, p-well regions 26 of pixels 11ᵢⱼ (i, j=1, 2) are covered with an n-well region 24 covering these p-well regions 26. Then, as illustrated in FIG. 2, the n-well region 24 is formed in a p-well region 23.

An amplification transistor AMP is formed in the p-well region 26 of the pixel 11₁₁, a reset transistor RST is formed in the p-well region 26 of the pixel 11₁₂, and a selection transistor SEL is formed in the p-well region 26 of the pixel 11₂₂. In the fifth embodiment, these transistors are n-channel transistors. Each of the p-well regions 26 of these transistors is provided with a terminal (pad) 25 for adjusting the potential of the p-well region 26, that is, the substrate potential. Furthermore, the n-well region 24 is provided with a terminal 28 that applies a potential VDD to the n-well region.

In the fifth embodiment, as in the case of the first embodiment, at the time of reading, Vwell is applied to the terminal 25 in order to adjust the potential of the p-well region 26 in which the selection transistor SEL is formed. Then, a potential VSS is applied to the terminals 25 of the amplification transistor AMP and the reset transistor RST.

The read operation of the imaging device configured as described above can be performed similarly to the case of the first embodiment. Hence, as in the case of the first embodiment, in the fifth embodiment, too, the substrate potential of the selection transistor SEL included in the pixel group can be adjusted at the time of reading, and the dynamic range can be increased easily. Furthermore, in the present embodiment, the substrate potential of the selection transistor SEL is adjusted, but the substrate potential of the reset transistor RST may be adjusted as in the second embodiment. Moreover, the substrate potentials of the selection transistor SEL and the reset transistor may be adjusted at the time of the read operation.

Furthermore, in the fifth embodiment, the pixel transistor is an n-channel transistor, but even if the pixel transistor is replaced with a p-channel transistor, the dynamic range can be increased easily as in the third embodiment and the fourth embodiment.

### Sixth Embodiment

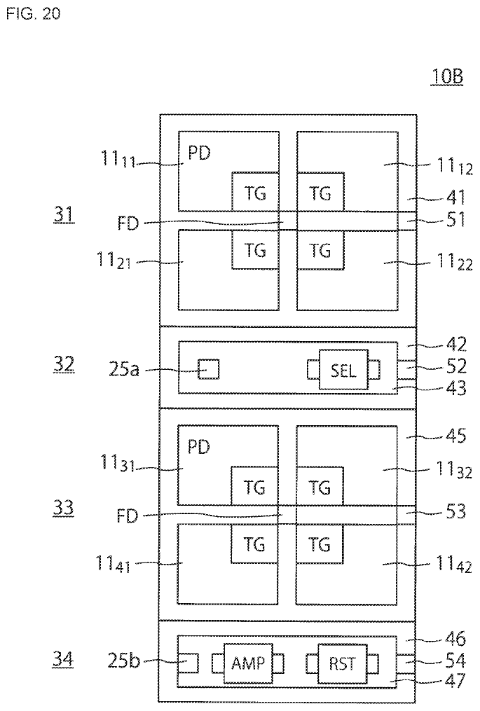

An imaging device according to a sixth embodiment will be described with reference to FIG. 20. FIG. 20 is a plan view of a pixel group used in the imaging device according to the sixth embodiment. The imaging device according to the sixth embodiment has a configuration of the imaging device illustrated in FIG. 1, in which the pixel group 10 illustrated in FIG. 1 is replaced by a pixel group 10B illustrated in FIG. 20. The pixel group 10B includes pixels 11i (i=1, . . . 4, j=1, 2) arranged in four rows and two columns. Pixels 11₁₁ to 11₂₂ are disposed in a region 31, include a photoelectric conversion element PD and a transfer gate TG, and are separated from each other by a p-well region 41. Each of pixels 11₃₁ to 11₄₂ includes the photoelectric conversion element PD and the transfer gate TG, and are separated from each other by a p-well region 45. A floating diffusion FD that accumulates signal charge of the pixels is provided in a central portion of the pixels 11₁₁ to 11₂₂, and the floating diffusion FD is connected to the photoelectric conversion element of each pixel via the corresponding transfer gate TG. The floating diffusion FD that accumulates signal charge of the pixels is provided in a central portion of the pixels 11₃₁ to 11₄₂, and the floating diffusion FD is connected to the photoelectric conversion element of each pixel via the corresponding transfer gate TG. A terminal (pad) 51 is provided on the p-well region 41 of the region 31, and a potential VSS is supplied to the terminal 51. Furthermore, a terminal (pad) 53 is provided on the p-well region 45 of a region 33, and the potential VSS is supplied to the terminal 53.

A region 32 is arranged between the region 31 and the region 33 along the row direction of the pixel groups. The region 32 is provided with a p-well region 43 surrounded by an n-well region 42, and the p-well region 43 is provided with an n-channel selection transistor SEL and a terminal (pad) 25a for adjusting the potential of the p-well region 43. The n-well region 32 is provided with a terminal (pad) 52 to which a potential VDD is applied. Furthermore, a region 34 is arranged on the opposite side of the region 32 with respect to the region 33. In the region 34, a p-well region 47 surrounded by an n-well region 46 is provided, and the p-well region 47 is provided with an n-channel amplification transistor AMP, a reset transistor RST, and a terminal (pad) 25b for adjusting the potential of the p-well region 47. Furthermore, the n-well region 46 is provided with a terminal (pad) 54 to which the potential VDD is applied.

In the imaging device according to the sixth embodiment configured as described above, by adjusting the substrate potential of at least one of the selection transistor SEL or the reset transistor RST via the terminal 25, as in the case of the first embodiment or the second embodiment, the dynamic range can be increased easily at the time of reading.

### Seventh Embodiment

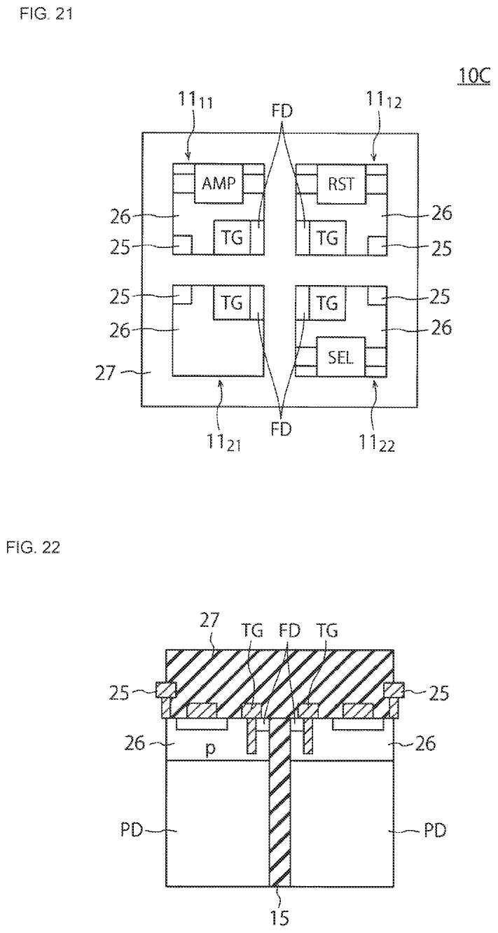

An imaging device according to a seventh embodiment will be described with reference to FIGS. 21 and 22. FIG. 21 illustrates a pixel group used in the imaging device according to the seventh embodiment, and FIG. 22 is a schematic cross-sectional view of the pixel group. The imaging device according to the seventh embodiment has a configuration in which the pixel group 10 according to the first embodiment illustrated in FIG. 1 is replaced with a pixel group 100 illustrated in FIG. 21.

The pixel group 100 includes pixels 11₁₁ to 11₂₂ arranged in two rows and two columns, and these pixels are separated by an insulating film 27 surrounding these pixels. Each pixel 11 (i, j=1, 2) includes a photoelectric conversion element PD and a p-well region 26 provided on the photoelectric conversion element PD (FIG. 2). The adjacent photoelectric conversion elements PD are separated by an insulating film 15 embedded in a trench (FIG. 2). The p-well region 26 of the pixel 11₁₁ is provided with an amplification transistor AMP, the floating diffusion FD, the transfer gate TG, and a terminal (pad) 25 that applies a potential to the p-well region 26. The p-well region 26 of the pixel 11₁₂ is provided with a reset transistor RST, the floating diffusion FD, the transfer gate TG, and the terminal (pad) 25 that applies a potential to the p-well region 26. The p-well region 26 of the pixel 11₂₂ is provided with a selection transistor SEL, the floating diffusion FD, the transfer gate TG, and the terminal (pad) 25 that applies a potential to the p-well region 26.

In the seventh embodiment, in a case where the dynamic range is increased by adjusting the substrate potential of the selection transistor SEL at the time of a read operation, for example, a potential VWll is supplied to the terminal 25 of the p-well region 26 of the pixel 11₂₂, and a potential VSS is supplied to the terminal 25 of the p-well region 26 of the pixels 11₁₁ and 11₁₂, similarly to the case of the first embodiment.

As in the case of the first embodiment, in the seventh embodiment configured as described above, too, the dynamic range can be increased easily at the time of reading.

### Eighth Embodiment

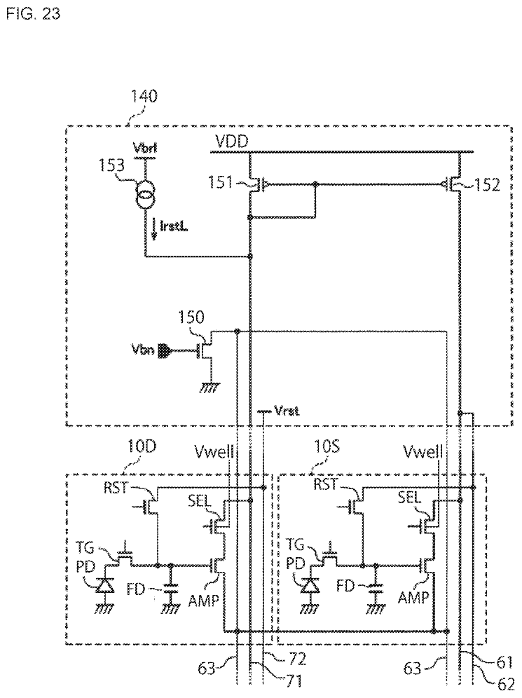

FIG. 23 illustrates a configuration of an imaging device according to an eighth embodiment. The imaging device according to the eighth embodiment has a configuration in which, in the imaging device according to the first embodiment, each of the pixel groups 10 arranged in the same column is replaced with a set including a pixel group 10S and a dummy pixel group 10D illustrated in FIG. 23, and a differential amplification unit 140 illustrated in FIG. 23 is provided corresponding to each column.

The pixel group 10S has the same configuration as the pixel group 10 according to the first embodiment, and the dummy pixel group 10D has the same configuration as the pixel group 10 according to the first embodiment except that the dummy pixel group 10D is shielded by a metal film or the like so that incident light does not enter the photoelectric conversion element PD.

The differential amplification unit 140 includes an n-channel MOS tail current source (hereinafter also referred to as tail current source) 150 and a current mirror circuit. The current mirror circuit includes p-channel load transistors (hereinafter also referred to as load transistors) 151 and 152 and a reset-dedicated constant current circuit 153.

The tail current source 150 is connected to the sources of the amplification transistors AMP of the pixel group 10S and the dummy pixel group 10D via a column Vcom line 63. A bias voltage Vbn is applied to the gate of the tail current source 150, and a constant current flows through the amplification transistor AMP.

The drain of one load transistor 151 constituting the current mirror circuit is connected to the drain of the selection transistor SEL of the dummy pixel group 10D via a column signal line 71. The drain of the other load transistor 152 constituting the current mirror circuit is connected to the drain of the selection transistor SEL of the pixel group 10S via a column signal line 61. The sources of the load transistors 151 and 152 are connected to a constant voltage source VDD.

The load transistors 151 and 152 constituting the current mirror circuit cause an equal current to flow through the column signal line 71 on the dummy pixel group 10D side and the column signal line 61 on the pixel group 10S side.

The reset-dedicated constant current circuit 153 is also connected to the column signal line 71 of the dummy pixel group 10D. The reset-dedicated constant current circuit 153 is a circuit that is connected between a constant voltage source Vbrl and the drain of the load transistor 151 and causes a predetermined current value IrstL to flow. Specifically, different currents flow to the reference side of the differential pair in the reset period and the readout period. As a result, different currents flow through the reference side and the signal side of the differential pair during the reset period.

The drain of the reset transistor RST of the dummy pixel group 10D is connected to a column reset line 72, and a reset voltage Vrst is supplied to the column reset line 72.

On the other hand, the drain of the reset transistor RST of the pixel group 10S is connected to a column reset line 62, and the column reset line 62 is connected to the column signal line 41.

The differential amplification unit 140 constitutes a differential amplifier together with the amplification transistor AMP and the selection transistor SEL of the dummy pixel group 10D and the amplification transistor AMP and the selection transistor SEL of the pixel group 10S.

As described above, by providing the dummy pixel group corresponding to each of the pixel groups arranged in each column and the differential amplification unit corresponding to each column in the first embodiment, similarly to Patent Document 2 filed and published by the applicant of the present application, it is possible to change the current flowing through the amplification transistor AMP of each of the pixel group 10S and the dummy pixel group 10D in the reset period and the readout period, and it is possible to adjust the potential of the column signal line 61 to an optimum operating point (operating range) of the differential amplifier above the operating point unique to the differential amplifier. As a result, the conversion efficiency of the amplification transistor of the pixel group 10S can be improved, the linearity can be improved, and the dynamic range can be further increased as compared with the first embodiment.

Note that in the eighth embodiment, as illustrated in FIG. 23, the pixel group 10S, the dummy pixel group 10D, and the differential amplification unit 140 are newly added instead of the pixel group 10 according to the first embodiment. Even in a configuration in which any of the pixel groups according to the second to seventh embodiments is replaced with the pixel group, the dummy pixel group, and the operation amplification unit, the dynamic range can be increased easily as in the eighth embodiment.

### Application Example

The technology according to the present disclosure can be applied to various products. For example, the technology according to the present disclosure may also be realized as a device mounted on any type of mobile body such as an automobile, an electric automobile, a hybrid electric automobile, a motorcycle, a bicycle, a personal mobility, an airplane, a drone, a ship, a robot, a building machine, or an agricultural machine (tractor).

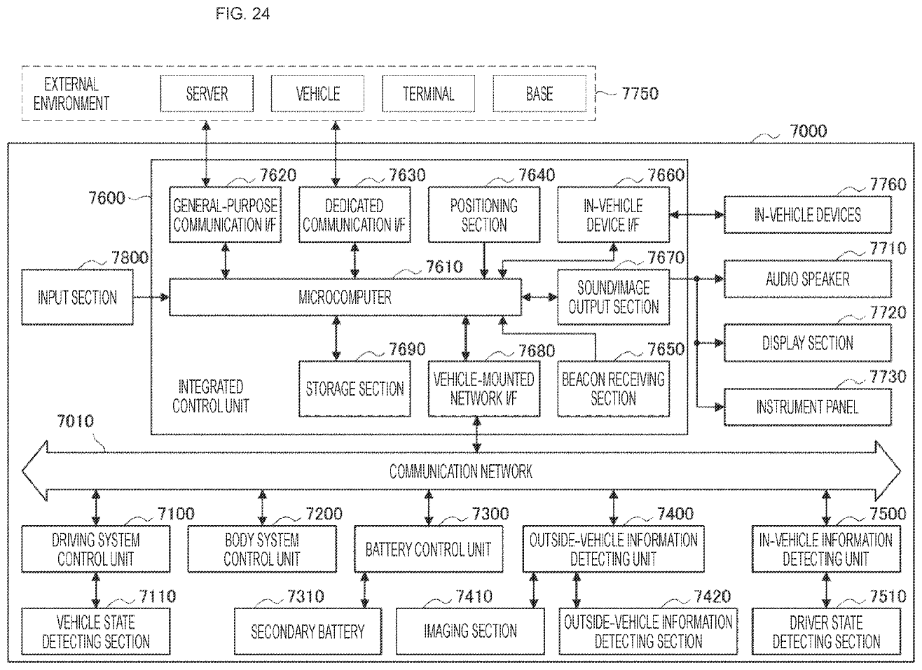

FIG. 24 is a block diagram illustrating an example of schematic configuration of a vehicle control system 7000 as an example of a mobile body control system to which the technology according to the present disclosure can be applied. The vehicle control system 7000 includes a plurality of electronic control units connected to each other via a communication network 7010. In the example illustrated in FIG. 24, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 24 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

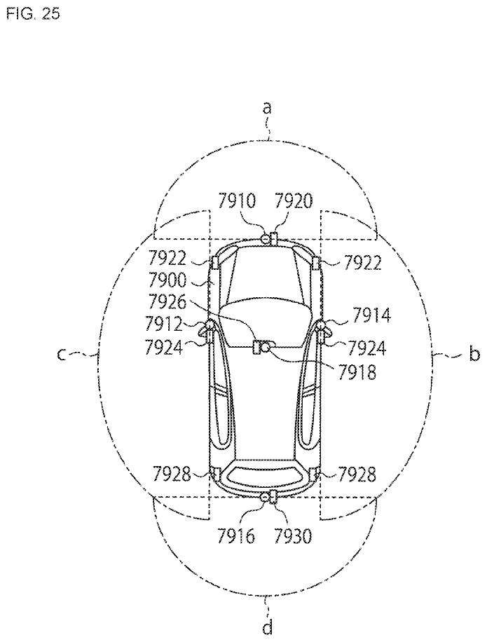

Here, FIG. 25 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 25 illustrates an example of imaging ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 24, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 24, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that at least two control units connected to each other via the communication network 7010 in the example illustrated in FIG. 24 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the imaging devices according to the first to eighth embodiments can be used as the imaging section 7410 illustrated in FIG. 24 or the imaging sections 7910 to 7916 illustrated in FIG. 22.

The preferred embodiments of the present disclosure have been described above in detail with reference to the accompanying drawings, but the technical scope of the present disclosure is not limited to such examples. It is clear that one of ordinary skill in the technical field of the present disclosure may conceive of various modifications and corrections within the scope of the technical idea recited in claims. It is understood that they also naturally belong to the technical scope of the present disclosure.

Furthermore, the effects described in the present specification are merely explanatory or exemplary, and are not restrictive. That is, the technology according to the present disclosure may provide other effects that are apparent to those skilled in the art from the description of the present specification, in addition to or instead of the abovementioned effects.

Note that the following configurations also belong to the technical scope of the present disclosure.
(1) An imaging device including: a pixel array unit arranged in a matrix in units of a pixel group including a plurality of pixels that performs photoelectric conversion; a pixel transistor provided corresponding to each pixel group and including a plurality of transistors; and a circuit that controls a threshold voltage of at least one transistor of the plurality of transistors.
(2) The imaging device according to (1), in which the pixel transistor includes a reset transistor, an amplification transistor, and a selection transistor.
(3) The imaging device according to (2), in which the transistor whose threshold voltage is controlled is at least one of the reset transistor or the selection transistor.
(4) The imaging device according to any one of (1) to (3), in which the transistor whose threshold voltage is controlled is arranged in a well region, and the circuit controls a potential applied to the well region.
(5) The imaging device according to any one of (1) to (4), in which the plurality of transistors constituting the pixel transistor includes n-channel MOS transistors.
(6) The imaging device according to any one of (1) to (4), in which the plurality of transistors constituting the pixel transistor includes p-channel MOS transistors.
(7) The imaging device according to any one of (1) to (6), in which each of the plurality of pixels includes a photoelectric conversion element arranged in a first region and a well region arranged in a second region on the first region, the well regions in the plurality of pixels being separated by an insulating film.
(8) The imaging device according to (8), in which the pixel includes a floating diffusion that accumulates charge converted by the photoelectric conversion element and a transfer gate that transfers the charge accumulated in the floating diffusion to the pixel transistor, the floating diffusion and the transfer gate being arranged in the first region.
(9) The imaging device according to (8), in which the pixel includes a floating diffusion that accumulates charge converted by the photoelectric conversion element, and a transfer gate that transfers the charge accumulated in the floating diffusion to the pixel transistor, and the floating diffusion and the transfer gate are arranged in the second region.
(10) The imaging device according to any one of (1) to (9), in which each of the plurality of pixels includes a photoelectric conversion element and a well region arranged on the photoelectric conversion element and in which the pixel transistor is arranged, the well region being covered with a semiconductor region having a conductivity type different from a conductivity type of the well region.
(11) The imaging device according to any one of (1) to (10), in which the plurality of transistors of the pixel transistor is provided corresponding to different pixels.
(12) The imaging device according to (1), in which: the pixel group includes a first region, a second region, a third region, and a fourth region arranged in a plane direction of the pixel array unit; the first region includes a first pixel group; the second region includes a second pixel group; the third region is arranged between the first region and the second region and includes a first portion of the pixel transistor; and the fourth region is arranged on an opposite side of the third region with the second region interposed therebetween and includes a second portion of the pixel transistor.
(13) The imaging device according to (12), in which: the first pixel group includes a plurality of first pixels, each of the plurality of first pixels being separated by a first semiconductor region of a first conductivity type; the second pixel group includes a plurality of second pixels, each of the plurality of second pixels being separated by a second semiconductor region of the first conductivity type; the first portion is arranged in a first well region of the first conductivity type, the first well region being separated by a third semiconductor region of a second conductivity type different from the first conductivity type; and the second portion is arranged in a second well region of the first conductivity type, the second well region being separated by a fourth semiconductor region of the second conductivity type.
(14) The imaging device according to any one of (1) to (13) further including a differential amplification unit, in which the pixel array unit includes a first pixel group including a first pixel and a second pixel group including a second pixel, and is configured such that incident light is incident on a photoelectric conversion element included in the first pixel and the incident light is not incident on a photoelectric conversion element included in the second pixel, and the differential amplification unit causes different currents to flow in the first pixel group and the second pixel in a reset period and a readout period.
(15) The imaging device according to (14), in which the pixel transistor includes a reset transistor, an amplification transistor, and a selection transistor, and the differential amplification unit includes a tail current source that causes a constant current to flow through the amplification transistor of each of the first pixel group and the second pixel group, and a current mirror circuit that causes an equal current to flow through the first pixel group and the second pixel group.
(16) The imaging device according to (15), in which the differential amplification unit further includes a reset constant current circuit that causes a predetermined current to flow through the second pixel group during a reset period.
(17) A method for driving an imaging device including a pixel array unit arranged in a matrix in units of a pixel group including a plurality of pixels that performs photoelectric conversion, and a pixel transistor provided corresponding to each pixel group and including a plurality of transistors, the method including controlling a substrate potential of at least one transistor of the plurality of transistors during a readout period to control a threshold voltage of the transistor.
(18) The method for driving an imaging device according to (17), in which the transistor includes an n-channel transistor, and a positive pulse voltage is applied to the transistor during the readout period.
(19) The method for driving an imaging device according to (17), in which the transistor includes an n-channel transistor, and a negative pulse voltage is applied to the transistor during the readout period.
(20) An electronic device including an imaging device, and a signal processing unit that performs signal processing on the basis of a pixel signal imaged by the imaging device, in which the imaging device includes a pixel array unit arranged in a matrix in units of a pixel group including a plurality of pixels that performs photoelectric conversion, a pixel transistor provided corresponding to each pixel group and including a plurality of transistors, and a circuit that controls a threshold voltage of at least one transistor of the plurality of transistors.

### REFERENCE SIGNS LIST

10, 10A, 10B, 10C, 10S Pixel group
10D Dummy pixel group
11₁₁ to 11₂₂, 11₃₁ to 11₄₂ Pixel
12 Semiconductor layer
15 Insulating film
20 Pixel transistor
21 Source region/drain region
22 Layer
25 Terminal (pad)
26 p-well region
27 Insulating film
40 Signal charge
81 Arrow
82 Arrow
83 Arrow
FD Floating diffusion
PD Photoelectric conversion element (photodiode)
AMP Amplification transistor
RST Reset transistor
SEL Selection transistor
TG Transfer gate
250 Imaging device
251 Pixel region
252 Pixel drive line
253 Vertical signal line
254 Vertical drive unit
255 Column processing unit
256 Horizontal drive unit
257 System control unit
258 Signal processing unit
259 Memory unit
7000 Vehicle control system
7010 Communication network
7100 Driving system control unit
7110 Vehicle state detecting section
7200 Body system control unit
7300 Battery control unit
7310 Secondary battery
7400 Outside-vehicle information detecting unit
7410 Imaging section
7420 In-vehicle information detecting section
7500 In-vehicle information detecting unit
7510 Driver state detecting section
7600 Integrated control unit
7610 Microcomputer
7620 General-purpose communication I/F
7630 Dedicated communication I/F
7640 Positioning section
7650 Beacon receiving section
7660 In-vehicle device I/F
7670 Sound/image output section
7680 Vehicle-mounted network I/F
7690 Storage section
7710 Audio speaker
7720 Display section
7730 Instrument panel
7750 External environment
7760 In-vehicle devices
7800 Input section
7900 Vehicle
7910 to 7916 Imaging section
7920 to 7930 Outside-vehicle information detecting section

1. An imaging device comprising:
a pixel array unit arranged in a matrix in units of a pixel group including a plurality of pixels that performs photoelectric conversion;
a pixel transistor provided corresponding to each pixel group and including a plurality of transistors; and
a circuit that controls a threshold voltage of at least one transistor of the plurality of transistors.

2. The imaging device according to claim 1, wherein
the pixel transistor includes a reset transistor, an amplification transistor, and a selection transistor.

3. The imaging device according to claim 2, wherein
the transistor whose threshold voltage is controlled is at least one of the reset transistor or the selection transistor.

4. The imaging device according to claim 1, wherein
the transistor whose threshold voltage is controlled is arranged in a well region, and the circuit controls a potential applied to the well region.

5. The imaging device according to claim 1, wherein
the plurality of transistors constituting the pixel transistor includes n-channel MOS transistors.

6. The imaging device according to claim 1, wherein
the plurality of transistors constituting the pixel transistors includes p-channel MOS transistors.

7. The imaging device according to claim 1, wherein
each of the plurality of pixels includes a photoelectric conversion element arranged in a first region and a well region arranged in a second region on the first region, the well regions in the plurality of pixels being separated by an insulating film.

8. The imaging device according to claim 7, wherein
the pixel includes a floating diffusion that accumulates charge converted by the photoelectric conversion element and a transfer gate that transfers the charge accumulated in the floating diffusion to the pixel transistor, the floating diffusion and the transfer gate being arranged in the first region.

9. The imaging device according to claim 7, wherein
the pixel includes a floating diffusion that accumulates charge converted by the photoelectric conversion element and a transfer gate that transfers the charge accumulated in the floating diffusion to the pixel transistor, the floating diffusion and the transfer gate being arranged in the second region.

10. The imaging device according to claim 1, wherein
each of the plurality of pixels includes a photoelectric conversion element and a well region arranged on the photoelectric conversion element and in which the pixel transistor is arranged, the well region being covered with a semiconductor region having a conductivity type different from a conductivity type of the well region.

11. The imaging device according to claim 1, wherein
the plurality of transistors of the pixel transistor is provided corresponding to different pixels.

12. The imaging device according to claim 1, wherein:
the pixel group includes a first region, a second region, a third region, and a fourth region arranged in a plane direction of the pixel array unit;
the first region includes a first pixel group;
the second region includes a second pixel group;
the third region is arranged between the first region and the second region and includes a first portion of the pixel transistor; and
the fourth region is arranged on an opposite side of the third region with the second region interposed therebetween and includes a second portion of the pixel transistor.

13. The imaging device according to claim 12, wherein:
the first pixel group includes a plurality of first pixels, each of the plurality of first pixels being separated by a first semiconductor region of a first conductivity type;
the second pixel group includes a plurality of second pixels, each of the plurality of second pixels being separated by a second semiconductor region of the first conductivity type;
the first portion is arranged in a first well region of the first conductivity type, the first well region being separated by a third semiconductor region of a second conductivity type different from the first conductivity type; and
the second portion is arranged in a second well region of the first conductivity type, the second well region being separated by a fourth semiconductor region of the second conductivity type.

14. The imaging device according to claim 1 further comprising a differential amplification unit, wherein
the pixel array unit includes a first pixel group including a first pixel and a second pixel group including a second pixel, and is configured such that incident light is incident on a photoelectric conversion element included in the first pixel and the incident light is not incident on a photoelectric conversion element included in the second pixel, and
the differential amplification unit causes different currents to flow in the first pixel group and the second pixel in a reset period and a readout period.

15. The imaging device according to claim 14, wherein
the pixel transistor includes a reset transistor, an amplification transistor, and a selection transistor, and
the differential amplification unit includes a tail current source that causes a constant current to flow through the amplification transistor of each of the first pixel group and the second pixel group, and a current mirror circuit that causes an equal current to flow through the first pixel group and the second pixel group.

16. The imaging device according to claim 15, wherein
the differential amplification unit further includes a reset constant current circuit that causes a predetermined current to flow through the second pixel group during a reset period.

17. A method for driving an imaging device including a pixel array unit arranged in a matrix in units of a pixel group including a plurality of pixels that performs photoelectric conversion, and a pixel transistor provided corresponding to each pixel group and including a plurality of transistors, the method comprising
controlling a substrate potential of at least one transistor of the plurality of transistors during a readout period to control a threshold voltage of the transistor.

18. The method for driving an imaging device according to claim 17, wherein
the transistor includes an n-channel transistor, and a positive pulse voltage is applied to the transistor during the readout period.

19. The method for driving an imaging device according to claim 17, wherein
the transistor includes an n-channel transistor, and a negative pulse voltage is applied to the transistor during the readout period.

20. An electronic device comprising
an imaging device, and
a signal processing unit that performs signal processing on a basis of a pixel signal imaged by the imaging device, wherein
the imaging device includes
a pixel array unit arranged in a matrix in units of a pixel group including a plurality of pixels that performs photoelectric conversion,
a pixel transistor provided corresponding to each pixel group and including a plurality of transistors, and
a circuit that controls a threshold voltage of at least one transistor of the plurality of transistors.
